(19) United States
(12) Patent Application Publication
(10) Pub. No.: US 2010/0304575 A1
(43) Pub. Date: Dec. 2, 2010

(54) METHOD AND ARRANGEMENT FOR TEMPERING SIC WAFERS

(76) Inventors: Uwe Keim, Grabenstetten (DE); Robert Michael Hartung, Blaubeuren (DE)

Correspondence Address: TAROLLI, SUNDHEIM, COVELL & TUMMINO L.L.P., 1300 EAST NINTH STREET, SUITE 1700, CLEVELAND, OH, 44114, US

(21) Appl. No.: 12/747,283

(22) PCT Filed: Dec. 10, 2008
(86) PCT No.: PCT/EP08/67197

§ 371 Date: Aug. 16, 2010

(30) Foreign Application Priority Data
Dec. 11, 2007 (DE) 10 2007 059 814.0

(51) Int. Cl. H01L 21/324; F27D 7/02

(52) U.S. Cl. 438/796; 432/219; 257/E21.211

(57) ABSTRACT

The invention relates to a method and an arrangement for tempering SiC wafers. The invention is to provide a method and an arrangement for tempering SiC wafers for generating a sufficient silicon partial pressure in the processing chamber and while reducing the operating costs. This is achieved in that a source for at least vaporized or gaseous silicon to increase the silicon partial pressure is connected to the processing chamber (2) for receiving at least one wafer (3), wherein said source is a vaporizer (4) having liquefied silicon fragments (11), to which a carrier gas can be supplied, which generates a gas flow via a silicone melt, and the vaporizer (4) is connected via a pipeline (5) to the processing chamber (2) or is disposed therein.

### FIELD OF THE INVENTION

The invention relates to a method and an apparatus for a annealing SiC-Wafers.

### BACKGROUND OF THE INVENTION

Silicon carbide wafers (SiC-wafers) as well as silicon disks have to be annealed, which is also called healed or tempered, after implanting impurities therein (for example Al, P, B) in order to incorporate the impurities in the SiC crystal structure, in order to make them electrically conductive. The damage which is generated by implanting impurities into a crystal structure can only be “healed” partially during this annealing process. This process typically occurs in a high-temperature process at temperatures between 1600-2000° C. in the process chamber of an annealing oven for singles SiC-wafers or a plurality of SiC-wafers simultaneously.

At these temperatures, the problem occurs that first atomic layers of silicon may be stripped from the crystal structure of the silicon carbide layer (SIC) thereby damaging the smooth SiC surface, or a “step bunching” occurs, i.e. crystal structures may be shifted within the wafer.

In order to provide relief to these problems, it is possible to introduce silan into the process chamber thereby enabling an increase of the silicon partial pressure. Typically, a mixture of silan and an inert gas is used, wherein argon is used as the inert gas.

Silan (SiH₄) is, however, dangerous due to its tendency to spontaneously combust and is thus difficult and cumbersome to handle.

### SUMMARY OF THE INVENTION

It is therefore an object of the invention to provide a method and an apparatus for annealing of SiC-wafers, which enables generating a sufficient Si partial pressure in the process chamber with reduced operating costs.

This object is solved by a method in which a plurality of SiC-wafers is introduced into a process chamber of an annealing oven and by generating a vacuum in the process chamber and concurrently heating the SiC-wafer to a process temperature of 1600-2000° C. and by increasing the Si partial pressure in the atmosphere of the process chamber to a value above the vapor pressure of the silicon bound in the Si-wafer over a predetermined period of time at a constant process temperature.

In so doing, pure silicon in gas or vapor form or a mixture of a carrier gas and silicon in gas or vapor form may be introduced into the process chamber. The carrier gas may be argon, helium or H₂.

In the interest of a constant process temperature, the silicon in gas or vapor form or the mixture of carrier gas and silicon in gas or vapor form is introduced into the process chamber at a temperature above 1600° C.

In a specific embodiment of the invention, the silicon in gas or vapor form is generated by vaporization of silicon from an SiC surface. This can be the surface of a SiC-wafer or fragments thereof or of molten silicon.

Vaporization is carried out at a temperature above 1400° C.

The object of the invention is also achieved by an apparatus for annealing SiC-wafers which is characterized in that a source of at least silicon in vapor or gas form is connected to the process chamber for receiving at least one wafer, for increasing the Si partial pressure.

The source for silicon in vapor or gas form is a vaporizer, to which a carrier gas may be fed to generate a gas flow over molten silicon, wherein the vaporizer is connected to the process chamber via a conduit or is arranged therein.

In an embodiment of the invention the vaporizer is a box made of graphite, silicon carbide or from silicon coated graphite or tantalum carbide, ceramics, sapphire, or molybdenum.

The source for the silicon in vapor or gas form in the vaporizer is a silicon wafer or fragments of silicon or molten silicon in the vaporizer.

The vaporizer is arranged in the annealing oven below the process chamber in an area of the annealing oven which is at a temperature of 1450-1700° C. Thereby, the vaporizer does not need its own heating.

In another variation of the invention, the vaporizer is arranged within the process chamber below the wafers.

As a carrier gas a noble gas such as argon or helium or H₂ could be used. It is a requirement here to have an atmosphere free of oxygen.

The temperature in the vaporizer is in the range of 1450-1700° C. and the temperature in the process chamber lies between 1600 and 1900° C.

In accordance with the invention, an Si-wafer or a mixture of Si and a carrier gas is introduced into the process chamber from a vaporizer (bubbler).

### BRIEF DESCRIPTION OF THE DRAWINGS

The invention will be described herein below in more detail in accordance with an embodiment. In the respective drawings:

FIG. 1 shows a schematic representation of an inventive arrangement for annealing SiC-wafers, that arrangement having a vaporizer below the process chamber; and

FIG. 2 shows an enlarged representation of a vaporizer which is arranged at a lower end of the process chamber.

### DESCRIPTION OF THE PREFERRED EMBODIMENTS

The vaporizer 4 consists of a box below the process chamber 2 of an annealing oven 1, below a high-temperature area (up to 2000° C.), in which the SiC-Wafers 3 are tempered. The vaporizer 4 consists either of graphite, silicon graphite or of SiC coated graphite. The vaporizer can be made from materials such as tantalum carbide, sapphire, ceramics or molybdenum. In said vaporizer there is a silicon wafer 3.1 acting as a Si-vapor source or there may be silicon fragments, wherein the latter is preferred.

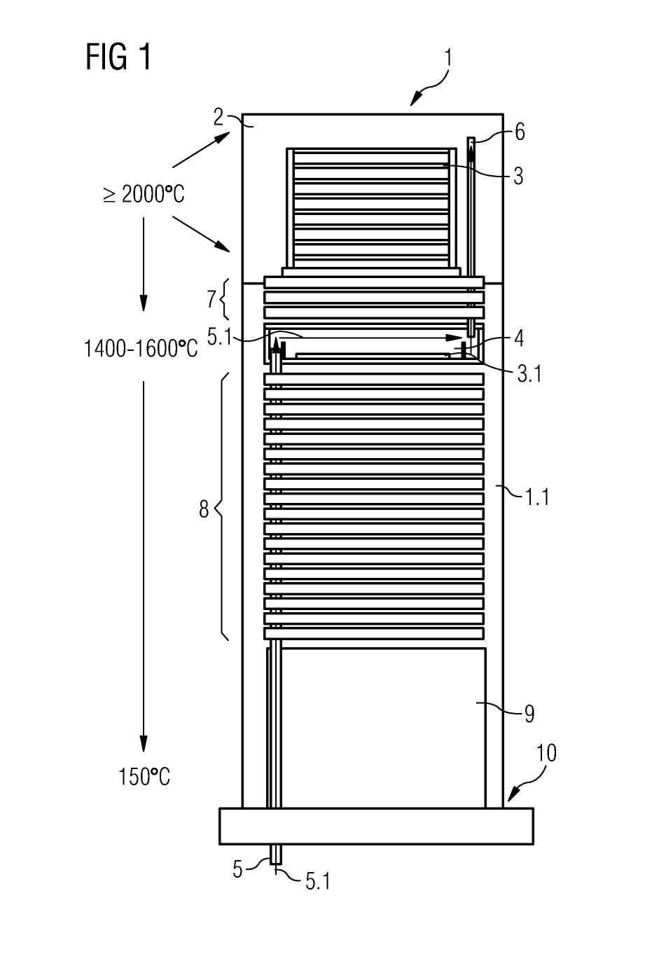

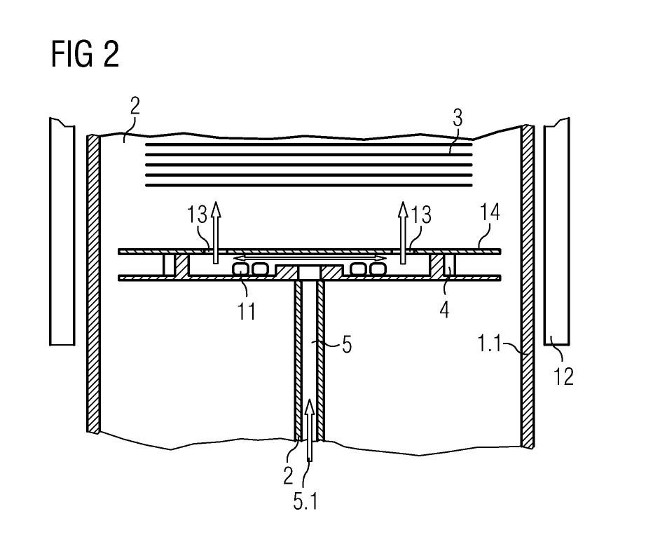

The required temperature in the vaporizer lies between 1400-1600° C., at least above the molting temperature of silicon (1414° C.). This temperature is achieved below heat insulation 7 and above insulating layers 8 below the process chamber 2 (FIG. 1). Thereby, liquid silicon 11 (FIG. 2) is generated from the SiC-wafer 3 (FIG. 1) in the vaporizer. Through this molting silicon or there over, a carrier gas may be conducted (bubbled). The carrier gas 5.1 may also be conducted over the surface of the molten silicon. Ar, H₂, He etc. may be used as the carrier gas 5.1.

When feeding the carrier gas 5.1 from a gas supply via the conduit 5 and during the subsequent conducting of the carrier gas 5.1 through the molten silicon, vaporized silicon is entrained and the gas mixture, for example Ar—Si, can then be conducted via a duct 6 (FIG. 1) to the SiC-wafers 3 in the process chamber 2 and may generate therein the required silicon partial pressure, which prevents vaporization of silicon from the SiC-wafers 3 to be annealed. The conduit 5 and the duct 6 may be made from SiC, ceramics, sapphire, molybdenum or graphite.

It is essential that through the invention it is possible to build up the required Si partial pressure in the process chamber 2 in a completely safe manner simply by the speed and volume of feeding the carrier gas.

The corresponding FIG. 1 shows a temperature oven 1 having a wall 1.1 and an upper high-temperature area up to 2000° C., in which the wafers 3 to be annealed are arranged in a process chamber 2.

Below the process chamber 2 there is a vaporizer 4 in a temperature range of above 1400° C. with a Si-wafer 3.1 which is molten at its surface (FIG. 1) or molten as Si-fragments 11 (FIG. 2). For feeding the carrier gas, a conduit 5 to a carrier gas source is provided and for feeding a mixture of carrier gas and Si to the process chamber 2 a duct 6 is provided.

In order to realize different temperature levels, there is provided a heat insulation 7 (C Baffle Layer) between the high-temperature area and the vaporizer 4 and below the vaporizer 4 a further heat insulation is provided consisting of a plurality of insulating layers 8 and a quartz baffle 9. This enables maintenance of a constant temperature of approx. 150° C. at the bottom area 10 of the annealing oven 1.

As can be seen from FIG. 2, the high-temperature area including the vaporizer 4 is surrounded by a heater 12. In contrast to FIG. 1, the vaporizer 4 is arranged in the lower section of the process chamber 2 according to FIG. 2, such that the vaporized carrier gas-/silicon-vapor-mixture may reach the wafers 3 in the process chamber 2 directly via openings 13 in a cover 14 of the vaporizer 4. Feeding of the required carrier gas again is achieved via the conduit 5. It is understood that the temperatures within the annealing oven 1 are generated by a heating device 12, which surrounds the process chamber 2 and the vaporizer 4.

In accordance with the inventive method, a stack of SiC-wafers 3.1 is loaded into a process chamber 2 of an annealing oven 1 and is heated within the process chamber to a process temperature of 1600-2000° C. while generating a vacuum, wherein at the same time the Si partial pressure in the atmosphere of the process chamber 2 is increased to a value above the vapor pressure of the silicon bound in the SiC-wafer 3.1 over a predetermined period of time at a constant process temperature.

Pure silicon in gas or vapor form or a mixture of a carrier gas and silicon in gas or vapor form may be introduced into the process chamber 2. Argon, helium or H₂ are considered for the carrier gas. The carrier gas is conducted along the molten fragments 11 (over 1414° C.) and thereby takes along silicon in vapor form to the process chamber (as shown by arrows in FIGS. 1, 2).

By arranging the vaporizer 4 in the process chamber 2 (FIG. 2) or below the process chamber (FIG. 1) as well as by the speed of the carrier gas and its volume, the silicon partial pressure in the process chamber may be adjusted.

In order to ensure a constant process temperature, the silicon in gas or vapor form or the mixture of the carrier gas and the silicon in gas or vapor form are introduced into the process chamber 2 at a temperature of above 1600° C. application:

1. Method for annealing SiC-wafers in a high-temperature area, comprising:
introducing a plurality of SiC-wafers (3) in a process chamber (2) of an annealing oven (1) and generating a vacuum in the process chamber (2),
simultaneously heating the SiC-wafer (3) to a process temperature of 1600-2000° C., and
2000° C. and increasing the Si partial pressure in the atmosphere of the process chamber (2) to a value above the vapor pressure of the silicon bound in the SiC-wafer for a predetermined period of time at a constant process temperature.

2. Method according to claim 1, wherein silicon in gas or vapor form is introduced into the process chamber (2).

3. The method of claim 1, wherein a mixture of a carrier gas and silicon in gas or vapor form is introduced into the process chamber (2).

4. The method of claim 3, wherein argon or helium is used as the carrier gas.

5. The method of claim 3, wherein H₂ is used as the carrier gas.

6-9. (canceled)

10. Apparatus for annealing SiC-wafers in a process chamber of an annealing oven in a high-temperature area, comprising a process chamber (2) for receiving at least one wafer (3), the process chamber (2) being connected to a source of at least silicon in vapor or gas form for increasing the silicon partial pressure.

11. The apparatus of claim 10, wherein the source for silicon in vapor or gas form is a vaporizer (4), to which a carrier gas may be fed to generate a flow of gas over molten silicon and in that the vaporizer (4) is connected to the process chamber (2) via a conduit (5) or is arranged therein.

12. The apparatus of claim 11, wherein the vaporizer (4) is a box, consisting of graphite, silicon-carbide or silicon coated graphite or tantalum carbide, ceramics, sapphire or molybdenum.

13. The apparatus according to claim 10, wherein the source of silicon in vapor or gas form is a silicon wafer (3.1) or silicon fragments (11) or molten silicon in the vaporizer (4).

14. The apparatus according to claim 11, wherein the vaporizer (4) is arranged below the process chamber (2) within the annealing oven (1).

15. The apparatus according to claim 11, wherein the vaporizer (4) is arranged in the process chamber (2) below the wafer (3).

16. The apparatus according to claim 15, wherein the vaporizer (4) is arranged in a temperature range of 1450-1700° C. of the annealing oven (1).

17. The apparatus according to claim 10, wherein noble gases used a carrier gas.

18. The apparatus according to claim 10, wherein H₂ is used as carrier gas.

19. The apparatus according to claim 11, wherein the temperature in the vaporizer is between 1450 and 1600° C.

20. The apparatus according to claim 10, wherein the temperature in the process chamber lies between 1600 and 1900° C.

21. The method according to claim 1, wherein the use of SiC-wafers, silicon disks or fragments thereof in increasing the Si partial pressure.

22. The apparatus according to claim 10, wherein the source of at least silicon in vapor or gas form utilizes at least one of SiC-wafers, silicon disks or fragments thereof.

23. The method of claim 2, wherein the silicon in gas or vapor form is introduced into the process chamber (2) at a temperature of at least 1450° C.

24. The method of claim 23, wherein the silicon in gas or vapor form is generated by vaporizing silicon from an SiC-surface.

25. The method of claim 24, wherein vaporizing silicon from an SiC-surface comprises vaporizing silicon from the surface of an SiC-wafer (3.1), from fragments thereof and/or from molten silicon (11).

26. The method of claim 25, wherein the vaporization is carried out at a temperature of above 1400° C.

27. The method of claim 3, wherein the mixture of a carrier gas and the silicon in gas or vapor form is introduced into the process chamber (2) at a temperature of at least 1450° C.

28. The method of claim 27, wherein the silicon in gas or vapor form is generated by vaporizing silicon from an SiC-surface.

29. The method of claim 28, wherein vaporizing silicon from an SiC-surface comprises vaporizing silicon from the surface of an SiC-wafer (3.1), from fragments thereof and/or from molten silicon (11).

30. The method of claim 29, wherein the vaporization is carried out at a temperature of above 1400° C.
